(19) United States
(12) Patent Application Publication
(10) Pub. No.: US 2008/0036473 A1
(43) Pub. Date: Feb. 14, 2008

(54) Dual-slope charging relaxation oscillator for measuring capacitance

(76) Inventor: Hakan K. Jansson, Akersberga (SE)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/502,267

(22) Filed: Aug. 9, 2006

(51) Int. Cl. G01R 27/26

(52) U.S. Cl. 324/678

(57) ABSTRACT

An apparatus and method for measuring a capacitance on the sensor element using two charge rates. The two charge rates may be two charging rates, or alternatively, two discharging rates for discharging the sensor element. Alternatively, both the two charging and discharging rates may be used to measure the capacitance. The method may be performed by charging a sensor element of a sensing device for a fixed time at the first charging rate, and charging the sensor element at the second charging rate to reach a threshold voltage after charging the sensor element for the fixed time. The method may also be performed by discharging the sensor element for a fixed time at the first discharging rate, and discharging the sensor element at the second discharging rate to reach a threshold voltage after discharging the sensor element for the fixed time.

### TECHNICAL FIELD

This invention relates to the field of user interface devices and, in particular, to touch-sensing devices.

### BACKGROUND

Computing devices, such as notebook computers, personal data assistants (PDAs), and mobile handsets, have user interface devices, which are also known as human interface device (HID). One user interface device that has become more common is a touch-sensor pad. A basic notebook touch-sensor pad emulates the function of a personal computer (PC) mouse. A touch-sensor pad is typically embedded into a PC notebook for built-in portability. A touch-sensor pad replicates mouse x/y movement by using two defined axes which contain a collection of sensor elements that detect the position of a conductive object, such as a finger. Mouse right/left button clicks can be replicated by two mechanical buttons, located in the vicinity of the touchpad, or by tapping commands on the touch-sensor pad itself. The touch-sensor pad provides a user interface device for performing such functions as positioning a cursor, or selecting an item on a display. These touch-sensor pads may include multi-dimensional sensor arrays for detecting movement in multiple axes. The sensor array may include a one-dimensional sensor array, detecting movement in one axis. The sensor array may also be two dimensional, detecting movements in two axes. Alternatively, the touch-sensor pads may be a single sensor element.

FIG. 1A illustrates a conventional touch-sensor pad. The touch-sensor pad 100 includes a sensing surface 101 on which a conductive object may be used to position a cursor in the x- and y-axes, or to select an item on a display. Touch-sensor pad 100 may also include two buttons, left and right buttons 102 and 103, respectively. These buttons are typically mechanical buttons, and operate much like a left and right button on a mouse. These buttons permit a user to select items on a display or send other commands to the computing device.

FIG. 1B illustrates a conventional linear touch-sensor slider. The linear touch-sensor slider 110 includes a surface area 111 on which a conductive object may be used to position a cursor in the x-axes (or alternatively in the y-axes). The construct of touch-sensor slider 110 may be the same as that of touch-sensor pad 100. Touch-sensor slider 110 may include a one-dimensional sensor array. The slider structure may include one or more sensor elements that may be conductive traces. Each trace may be connected between a conductive line and a ground. By being in contact or in proximity on a particular portion of the slider structure, the capacitance between the conductive lines and ground varies and can be detected. The capacitance variation may be sent as a signal on the conductive line to a processing device. For example, by detecting the capacitance variation of each sensor element, the position of the changing capacitance can be pinpointed. In other words, it can be determined which sensor element has detected the presence of the conductive object, and it can also be determined the motion and/or the position of the conductive object over multiple sensor elements.

One difference between touch-sensor sliders and touch-sensor pads may be how the signals are processed after detecting the conductive objects. Another difference in that the touch-sensor slider is not necessarily used to convey absolute positional information of a conducting object (e.g., to emulate a mouse in controlling cursor positioning on a display) but, rather, may be used to actuate one or more functions associated with the sensing elements of the sensing device.

Sensing devices are typically coupled to a processing device to measure the capacitance on the sensing device. There are various known methods for measuring capacitance. For example, the processing device may include a relaxation oscillator to measure capacitance. Other methods may be used to measure capacitance, such as versus voltage phase shift measurement, resistor-capacitor charge timing, capacitive bridge divider, charge transfer, or the like.

FIG. 1C illustrates a conventional relaxation oscillator for measuring capacitance on a sensor element of a sensing device. The relaxation oscillator 150 is formed by the capacitance to be measured on capacitor 151, charging current source 152, comparator 153, and reset switch 154. The capacitor 151 is representative of the capacitance measured on a sensor element of a sensor array. The relaxation oscillator is coupled to drive a charging current (Ic) 157 in a single direction onto capacitor 151. As the charging current piles charge onto capacitor 151, the voltage across the capacitor increases with time as a function of Ic 157 and its capacitance C. Equation (1) describes the relation between current, capacitance, voltage and time for a charging capacitor.

CdV=I_{c}dt (1)

The relaxation oscillator begins by charging the capacitor 151 from a ground potential or zero voltage and continues to pile charge on the capacitor 151 at a fixed charging current Ic 157 until the voltage across the capacitor 151 at node 155 reaches a reference voltage or threshold voltage, V_{TH} 160. At the threshold voltage V_{TH} 160 the relaxation oscillator allows the accumulated charge at node 155 to discharge (e.g., the capacitor 151 to “relax” back to the ground potential) and then the process repeats itself. In particular, the output of comparator 153 asserts a clock signal F_{OUT} 156 (e.g., F_{OUT} 156 goes high), which enables the reset switch 154. This resets the voltage on the capacitor at node 155 to ground and the charge cycle starts again. The relaxation oscillator outputs a relaxation oscillator clock signal (F_{OUT} 156) having a frequency (f_{RO}) dependent upon capacitance C of the capacitor 151 and charging current Ic 157.

As previously mentioned, the charging current source 152 of relaxation oscillator 150 provides a current to the capacitor 151. This current, however, is a constant current for charging capacitance until the voltage at node 155 reaches a fixed threshold voltage V_{TH} 160 for measuring the charge time (relaxation oscillator period). Equation (2) describes the relation between charging current Ic 157, charge time (T), capacitance (C) and threshold voltage (V_{TH}) V_{TH} 160.

$${\int }_{0}^{T} \frac{{i}_{c} ( t )}{C} d t = {V}_{TH} \qquad ( 2 )$$

### For the conventional relaxation oscillator the charging current is constant, as represented in equation (3):

i(t)=i₁ (3)

### Which means the period (T) can be expressed as in the following equation, equation (4):

$$\begin{matrix}{\int }_{0}^{T} \frac{k \cdot {i}_{1}}{C} d t = {V}_{TH} \to {[ \frac{{i}_{1} \cdot t}{C} ]}_{t = 0}^{t = T} \\ = {V}_{TH} \to \frac{{i}_{1} \cdot T}{C} \\ = {V}_{TH} \to T \\ = \frac{{V}_{TH} \cdot C}{{i}_{1}}\end{matrix} \qquad ( 4 )$$

FIG. 1D illustrates a graph 175 of the voltage 159 on the capacitor 151 at node 155 with respect to time (t) as the capacitor is charged to the threshold voltage V_{TH} 160 using the conventional relaxation oscillator of FIG. 1C. The fixed charging current Ic 157 increases voltage 159, linearly over time, until the voltage reaches the voltage threshold V_{TH} 160. Once the voltage threshold has been reached, the relaxation oscillator 150 also discharges the voltage 159. The relaxation oscillator 150 may discharge the voltage 159 using an on/off reset switch. In other words, convention relaxation oscillator 150 uses only a single charging rate and a single discharging rate to measure the capacitance on the sensing device. The period of this charge-discharge cycle is proportional to the capacitance measured on the sensing device.

The conventional relaxation oscillator can improve its accuracy in measuring the capacitance by lowering the charging current (i₁) and/or increasing the number of charge cycles. This, however, may lead to longer measurement times. By increasing the measurement time, the power consumption of the sensing device increase, and may cause the relaxation oscillator to have sampling rates that are too low to measure the capacitance for certain applications. For example, some handwriting recognition applications require 80 positions per second.

### BRIEF DESCRIPTION OF THE DRAWINGS

The present invention is illustrated by way of example, and not by way of limitation, in the figures of the accompanying drawings.

FIG. 1A illustrates a conventional touch-sensor pad.

FIG. 1B illustrates a conventional linear touch-sensor slider.

FIG. 1C illustrates a conventional relaxation oscillator for measuring capacitance on a sensor element of a sensing device.

FIG. 1D illustrates a graph of the voltage on the capacitor with respect to time (t) as the capacitor is charged to the threshold voltage using the conventional relaxation oscillator of FIG. 1C.

FIG. 2 illustrates a block diagram of one embodiment of an electronic system having a processing device for detecting a presence of a conductive object.

FIG. 3A illustrates a varying switch capacitance.

FIG. 3B illustrates one embodiment of a sensing device coupled to a processing device.

FIG. 3C illustrates one embodiment of a relaxation oscillator.

FIG. 4A illustrates a block diagram of one embodiment of a capacitance sensor including a relaxation oscillator, a controller, and a digital counter.

FIG. 4B illustrates a block diagram of one embodiment of a dual-slope charging relaxation oscillator having a relaxation oscillator and a controller.

FIG. 4C illustrates a block diagram of one embodiment of a controller of a dual-slope charging relaxation oscillator.

FIG. 4D illustrates a block diagram of another embodiment of a controller of a dual-slope charging relaxation oscillator.

FIG. 5A illustrates a top-side view of one embodiment of a sensor array having a plurality of sensor elements for detecting a presence of a conductive object on the sensor array of a touch-sensor pad.

FIG. 5B illustrates a top-side view of one embodiment of a sensor array having a plurality of sensor elements for detecting a presence of a conductive object on the sensor array of a touch-sensor slider.

FIG. 5C illustrates a top-side view of one embodiment of a two-layer touch-sensor pad.

FIG. 5D illustrates a side view of one embodiment of the two-layer touch-sensor pad of FIG. 5C.

FIG. 6A illustrates a graph of one embodiment of the voltage on sensor element with respect to time as the capacitor is charged to the threshold voltage using the dual-slope charging relaxation oscillator of FIG. 4C.

FIG. 6B illustrates a graph for comparison of one embodiment of detecting a presence of a finger using the dual-slope charging relaxation oscillator of FIG. 4C with the conventional relaxation oscillator.

FIG. 7A illustrates a graph of one embodiment of detecting a presence of a finger using the dual-slope charging relaxation oscillator using two charging rates and two discharging rates.

FIG. 7B illustrates a graph of one embodiment of detecting a presence of a finger using the dual-slope charging relaxation oscillator using three charging rates and three discharging rates.

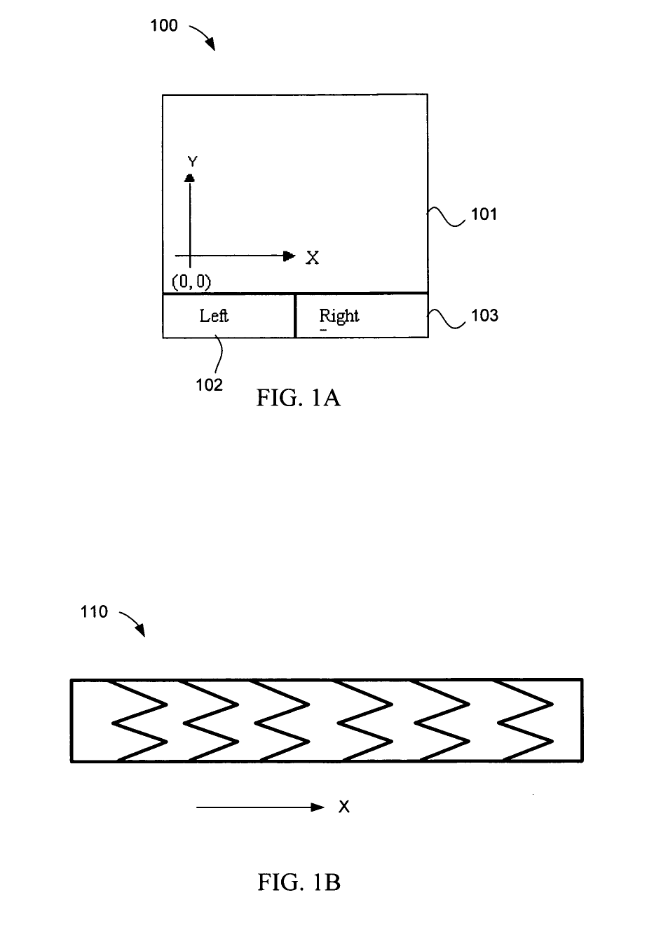

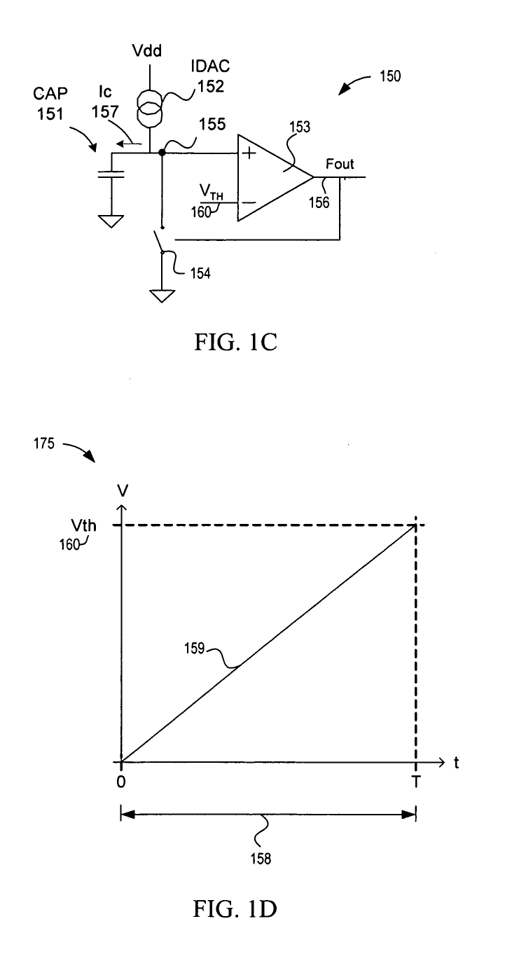

### DETAILED DESCRIPTION

Described herein is a method and apparatus for measuring a capacitance on the sensor element using two charge rates. The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

Embodiments of a method and apparatus are described to method and apparatus for measure a capacitance on the sensor element using two charge rates. The two charge rates may be two charging rates, or alternatively, two discharging rates for discharging the sensor element. Alternatively, both the two charging and discharging rates may be used to measure the capacitance. The method may be performed by charging a sensor element of a sensing device for a fixed time at the first charging rate, and charging the sensor element at the second charging rate to reach a threshold voltage after charging the sensor element for the fixed time. The method may also be performed by discharging the sensor element for a fixed time at the first discharging rate, and discharging the sensor element at the second discharging rate to reach a threshold voltage after discharging the sensor element for the fixed time.

As described in the embodiments herein, the capacitance that is to be measured is pre-charged using a higher charging current (Ic) for a fixed time and then charged using the nominal charging current to the fixed threshold voltage. The relaxation oscillator uses a higher charging current for a fixed time in order to charge (e.g., precharge) a capacitance to a fixed charge on a sensor element of a sensing device. Using two different charging currents creates the “dual-slope” waveform. This measurement achieves the same accuracy as the traditional relaxation oscillator method using the nominal charging current but it can do so significantly faster.

The charging current (Ic) using this new dual-slope approach is represented in equation (5), where t₀ is the fixed time selected for the first slope.

$$i ( t ) = \{ \begin{matrix}{i}_{0} , & t < {t}_{0} \\ {i}_{1} , & t > {t}_{0}\end{matrix} \qquad ( 5 )$$

Equation (6) describes the relation between the charging current (Ic), charge time (T), capacitance (C) and threshold voltage (V_{TH}).

$${\int }_{0}^{{i}_{0}} \frac{{i}_{0}}{c} d t + {\int }_{{t}_{0}}^{T} \frac{{i}_{1}}{c} d t = {V}_{TH} \qquad ( 6 )$$

The first charging current i₀ can be expressed as a constant multiplied by the second charging current i₁, as in equation (7).

i₀=k·i₁ (7)

### Substituting equation (7) into equation (6) and solving for T is represented in equations (8) and (9).

$$\begin{matrix}\begin{matrix}{\int }_{0}^{{t}_{0}} \frac{k \cdot {i}_{1}}{c} d t + {\int }_{{t}_{0}}^{T} \frac{{i}_{1}}{c} d t = {V}_{TH} \to {[ \frac{k \cdot {i}_{1} \cdot t}{c} ]}_{t = 0}^{t = {t}_{0}} + {[ \frac{{i}_{1} \cdot t}{c} ]}_{t = 0}^{t = {t}_{0}} \\ = {V}_{THt} \to \end{matrix} & ( 8 ) \\ \begin{matrix}\frac{k \cdot {i}_{1} \cdot {t}_{0}}{c} + \frac{{i}_{1} \cdot T}{c} - \frac{{i}_{1} \cdot {t}_{0}}{c} = {V}_{TH} \to T \\ = \frac{{V}_{TH} \cdot c}{{i}_{1}} - {t}_{0} \cdot ( k - 1 )\end{matrix} & ( 9 )\end{matrix}$$

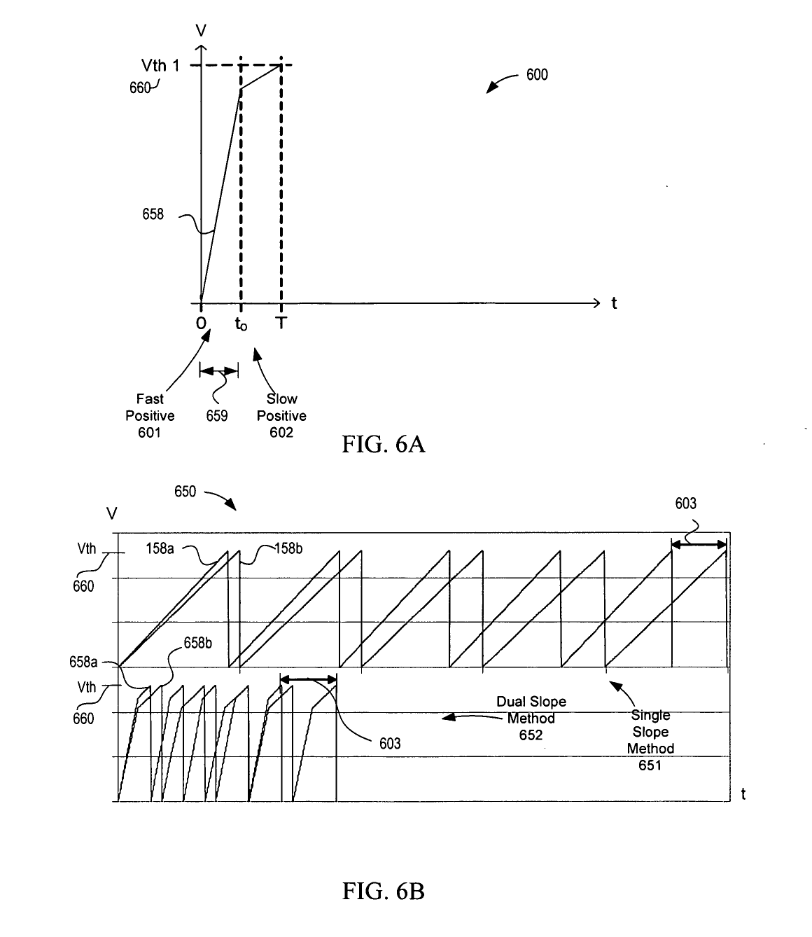

As can be seen in the equation above, equation (9), the sensitivity (dT/dc) is still the same as with the traditional approach but the actual period can be made much shorter by selecting appropriate values for the constant, k, and the fixed time, t₀. The fixed time t₀ can be programmable. Similarly, the threshold voltages may be programmable. A comparison of the charge curves for the conventional constant current charging relaxation oscillator and the dual-slope charging relaxation oscillator is illustrated and described with respect to FIG. 6B.

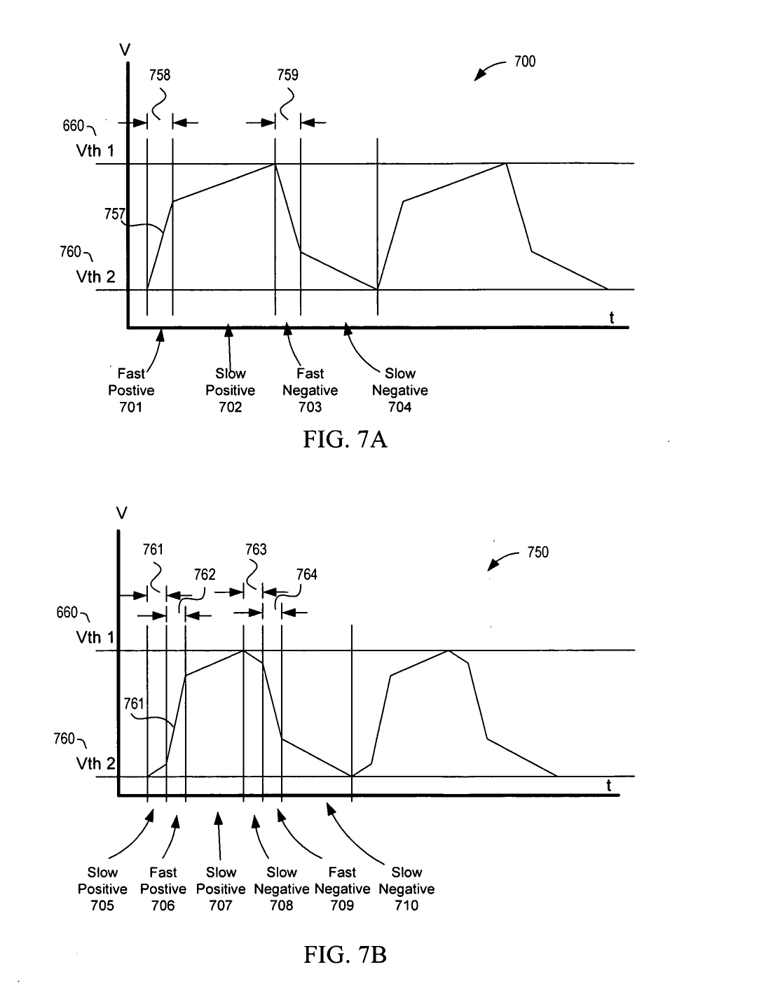

The dual-slope relaxation oscillator may discharge once the voltage threshold is reached, much like the conventional relaxation oscillator. Alternatively, the dual-slope approach can also be extended to the discharging of the capacitance in the relaxation oscillator creating a quad-slope waveform, as illustrated in FIGS. 7A and 7B. The negative slopes may be the same as the positive ones, although they could also be different. The discharge may be performed by reversing the charging direction. A second threshold voltage could be used to detect the end of the reversed charging. It should also be noted that the embodiments described herein are not limited to two charging and/or two discharging rates, but may include more than two charging rates and/or more than two discharging rates. For example, three charging and three charging rates are used in the embodiment that is illustrated in FIG. 7B.

A variation allows for the initial positive or negative slope to be briefly “slow.” This gives time to synchronize clocks, allowing for cleanly identifying the direction change before starting the time interval for the fast slope. (The oscillator formed by the capacitance is normally asynchronous to the clock that times the fast-slope interval.)

The embodiments described herein may permit the detection of a presence of a finger faster than the conventional relaxation oscillator. By increasing how fast the relaxation oscillator can detect the presence of the conductive object, higher sample rates may be used. Similarly, there are higher sensitivity, accuracy, and signal-to-noise ratios (SNR) in the sensing device, using the dual-slope relaxation oscillator. In addition, the power consumption of the device may be lowered using the embodiments described herein.

It should be noted that by improving the sampling rate, sensitivity, accuracy, SNR, and power consumption, the device may be beneficial in designing devices to have smaller sensing elements and/or thicker overlays, mechanical keys over the sensing device, collapsing overlays with cut-outs (air-gaps) for tactile feeling, transparent Indium Tin Oxide (ITO) capacitance sensors over an active radiating display, partially metallic overlays. The dual-sloped relaxation oscillator may also be beneficial in designing gloved finger input devices, increasing performance of inputting data using stylus pen, designing a device with different levels of sensing, proximity, presence, or pressure. In addition, it may be beneficial in handwriting recognition applications that require 80 positions per second.

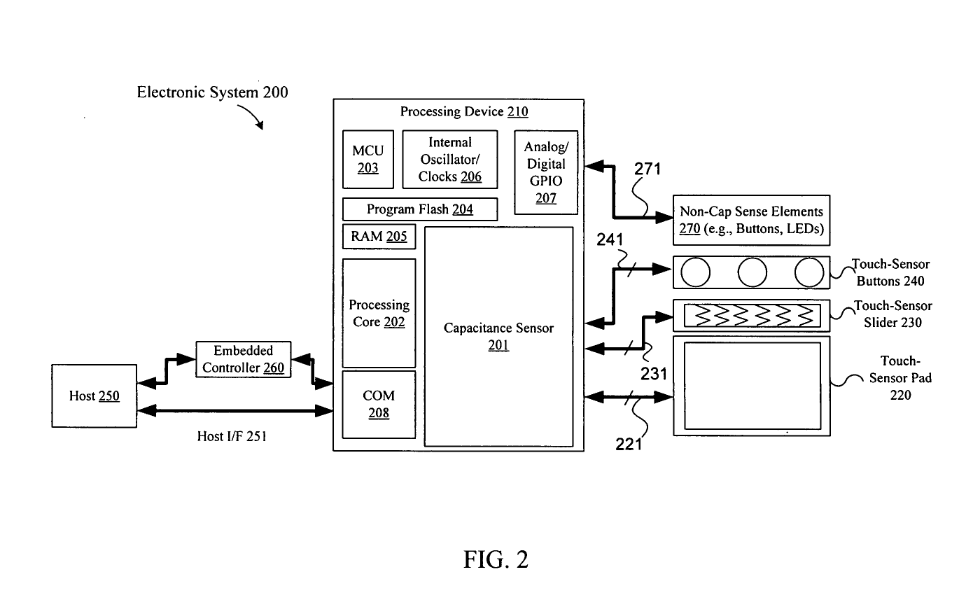

FIG. 2 illustrates a block diagram of one embodiment of an electronic system having a processing device for detecting a presence of a conductive object. Electronic system 200 includes processing device 210, touch-sensor pad 220, touch-sensor slider 230, touch-sensor buttons 240, host processor 250, embedded controller 260, and non-capacitance sensor elements 270. The processing device 210 may include analog and/or digital general purpose input/output (“GPIO”) ports 207. GPIO ports 207 may be programmable. GPIO ports 207 may be coupled to a Programmable Interconnect and Logic (“PIL”), which acts as an interconnect between GPIO ports 207 and a digital block array of the processing device 210 (not illustrated). The digital block array may be configured to implement a variety of digital logic circuits (e.g., DAC, digital filters, digital control systems, etc.) using, in one embodiment, configurable user modules (“UMs”). The digital block array may be coupled to a system bus. Processing device 210 may also include memory, such as random access memory (RAM) 205 and program flash 204. RAM 205 may be static RAM (SRAM), and program flash 204 may be a nonvolatile storage, which may be used to store firmware (e.g., control algorithms executable by processing core 202 to implement operations described herein). Processing device 210 may also include a memory controller unit (MCU) 203 coupled to memory and the processing core 202.

The processing device 210 may also include an analog block array (not illustrated). The analog block array is also coupled to the system bus. Analog block array also may be configured to implement a variety of analog circuits (e.g., ADC, analog filters, etc.) using, in one embodiment, configurable UMs. The analog block array may also be coupled to the GPIO 207.

As illustrated, capacitance sensor 201 may be integrated into processing device 210. Capacitance sensor 201 may include analog I/O for coupling to an external component, such as touch-sensor pad 220, touch-sensor slider 230, touch-sensor buttons 240, and/or other devices. Capacitance sensor 201 and processing device 202 are described in more detail below.

It should be noted that the embodiments described herein are not limited to touch-sensor pads for notebook implementations, but can be used in other capacitive sensing implementations, for example, the sensing device may be a touch-sensor slider 230, or a touch-sensor button 240 (e.g., capacitance sensing button). Similarly, the operations described herein are not limited to notebook cursor operations, but can include other operations, such as lighting control (dimmer), volume control, graphic equalizer control, speed control, or other control operations requiring gradual adjustments. It should also be noted that these embodiments of capacitive sensing implementations may be used in conjunction with non-capacitive sensing elements, including but not limited to pick buttons, sliders (ex. display brightness and contrast), scroll-wheels, multi-media control (ex. volume, track advance, etc) handwriting recognition and numeric keypad operation.

In one embodiment, the electronic system 200 includes a touch-sensor pad 220 coupled to the processing device 210 via bus 221. Touch-sensor pad 220 may include a multi-dimension sensor array. The multi-dimension sensor array comprises a plurality of sensor elements, organized as rows and columns. In another embodiment, the electronic system 200 includes a touch-sensor slider 230 coupled to the processing device 210 via bus 231. Touch-sensor slider 230 may include a single-dimension sensor array. The single-dimension sensor array comprises a plurality of sensor elements, organized as rows, or alternatively, as columns. In another embodiment, the electronic system 200 includes a touch-sensor button 240 coupled to the processing device 210 via bus 241. Touch-sensor button 240 may include a single-dimension or multi-dimension sensor array. The single- or multi-dimension sensor array comprises a plurality of sensor elements. For a touch-sensor button, the plurality of sensor elements may be coupled together to detect a presence of a conductive object over the entire surface of the sensing device. Alternatively, the touch-sensor button 240 has a single sensor element to detect the presence of the conductive object. In one embodiment, the touch-sensor button 240 may be a capacitance sensor element. Capacitance sensor elements may be used as noncontact switches. These switches, when protected by an insulating layer, offer resistance to severe environments.

The electronic system 200 may include any combination of one or more of the touch-sensor pad 220, touch-sensor slider 230, and/or touch-sensor button 240. In another embodiment, the electronic system 200 may also include non-capacitance sensor elements 270 coupled to the processing device 210 via bus 271. The non-capacitance sensor elements 270 may include buttons, light emitting diodes (LEDs), and other user interface devices, such as a mouse, a keyboard, or other functional keys that do not require capacitance sensing. In one embodiment, buses 271, 241, 231, and 221 may be a single bus. Alternatively, these buses may be configured into any combination of one or more separate buses.

The processing device may also provide value-added functionality such as keyboard control integration, LEDs, battery charger and general purpose I/O, as illustrated as non-capacitance sensor elements 270. Non-capacitance sensor elements 270 are coupled to the GPIO 207.

Processing device 210 may include internal oscillator/clocks 206 and communication block 208. The oscillator/clocks block 206 provides clock signals to one or more of the components of processing device 210. Communication block 208 may be used to communicate with an external component, such as a host processor 250, via host interface (I/F) line 251. Alternatively, processing block 210 may also be coupled to embedded controller 260 to communicate with the external components, such as host 250. Interfacing to the host 250 can be through various methods. In one exemplary embodiment, interfacing with the host 250 may be done using a standard PS/2 interface to connect to an embedded controller 260, which in turn sends data to the host 250 via low pin count (LPC) interface. In some instances, it may be beneficial for the processing device 210 to do both touch-sensor pad and keyboard control operations, thereby freeing up the embedded controller 260 for other housekeeping functions. In another exemplary embodiment, interfacing may be done using a universal serial bus (USB) interface directly coupled to the host 250 via host interface line 251. Alternatively, the processing device 210 may communicate to external components, such as the host 250 using industry standard interfaces, such as USB, PS/2, inter-integrated circuit (12C) bus, or system packet interfaces (SPI). The host 250 and/or embedded controller 260 may be coupled to the processing device 210 with a ribbon or flex cable from an assembly, which houses the sensing device and processing device.

In one embodiment, the processing device 210 is configured to communicate with the embedded controller 260 or the host 250 to send and/or receive data. The data may be a command or alternatively a signal. In an exemplary embodiment, the electronic system 200 may operate in both standard-mouse compatible and enhanced modes. The standard-mouse compatible mode utilizes the HID class drivers already built into the Operating System (OS) software of host 250. These drivers enable the processing device 210 and sensing device to operate as a standard cursor control user interface device, such as a two-button PS/2 mouse. The enhanced mode may enable additional features such as scrolling (reporting absolute position) or disabling the sensing device, such as when a mouse is plugged into the notebook. Alternatively, the processing device 210 may be configured to communicate with the embedded controller 260 or the host 250, using non-OS drivers, such as dedicated touch-sensor pad drivers, or other drivers known by those of ordinary skill in the art.

In other words, the processing device 210 may operate to communicate data (e.g., commands or signals) using hardware, software, and/or firmware, and the data may be communicated directly to the processing device of the host 250, such as a host processor, or alternatively, may be communicated to the host 250 via drivers of the host 250, such as OS drivers, or other non-OS drivers. It should also be noted that the host 250 may directly communicate with the processing device 210 via host interface 251.

In one embodiment, the data sent to the host 250 from the processing device 210 includes click, double-click, movement of the cursor, scroll-up, scroll-down, scroll-left, scroll-right, step Back, and step Forward. Alternatively, other user interface device commands may be communicated to the host 250 from the processing device 210. These commands may be based on gestures occurring on the sensing device that are recognized by the processing device, such as tap, push, hop, and zigzag gestures. Alternatively, other commands may be recognized. Similarly, signals may be sent that indicate the recognition of these operations.

In particular, a tap gesture, for example, may be when the finger (e.g., conductive object) is on the sensing device for less than a threshold time. If the time the finger is placed on the touchpad is greater than the threshold time it may be considered to be a movement of the cursor, in the x- or y-axes. Scroll-up, scroll-down, scroll-left, and scroll-right, step back, and step-forward may be detected when the absolute position of the conductive object is within a pre-defined area, and movement of the conductive object is detected.

Processing device 210 may reside on a common carrier substrate such as, for example, an integrated circuit (IC) die substrate, a multi-chip module substrate, or the like. Alternatively, the components of processing device 210 may be one or more separate integrated circuits and/or discrete components. In one exemplary embodiment, processing device 210 may be a Programmable System on a Chip (PSoC™) processing device, manufactured by Cypress Semiconductor Corporation, San Jose, Calif. Alternatively, processing device 210 may be one or more other processing devices known by those of ordinary skill in the art, such as a microprocessor or central processing unit, a controller, special-purpose processor, digital signal processor (DSP), an application specific integrated circuit (ASIC), a field programmable gate array (FPGA), or the like. In an alternative embodiment, for example, the processing device may be a network processor having multiple processors including a core unit and multiple microengines. Additionally, the processing device may include any combination of general-purpose processing device(s) and special-purpose processing device(s).

Capacitance sensor 201 may be integrated into the IC of the processing device 210, or alternatively, in a separate IC. Alternatively, descriptions of capacitance sensor 201 may be generated and compiled for incorporation into other integrated circuits. For example, behavioral level code describing capacitance sensor 201, or portions thereof, may be generated using a hardware descriptive language, such as VHDL or Verilog, and stored to a machine-accessible medium (e.g., CD-ROM, hard disk, floppy disk, etc.). Furthermore, the behavioral level code can be compiled into register transfer level (“RTL”) code, a netlist, or even a circuit layout and stored to a machine-accessible medium. The behavioral level code, the RTL code, the netlist, and the circuit layout all represent various levels of abstraction to describe capacitance sensor 201.

It should be noted that the components of electronic system 200 may include all the components described above. Alternatively, electronic system 200 may include only some of the components described above.

In one embodiment, electronic system 200 may be used in a notebook computer. Alternatively, the electronic device may be used in other applications, such as a mobile handset, a personal data assistant (PDA), a keyboard, a television, a remote control, a monitor, a handheld multi-media device, a handheld video player, a handheld gaming device, or a control panel.

In one embodiment, capacitance sensor 201 may be a capacitive switch relaxation oscillator (CSR). The CSR may have an array of capacitive touch switches using a current-programmable relaxation oscillator, an analog multiplexer, digital counting functions, and high-level software routines to compensate for environmental and physical switch variations. The switch array may include combinations of independent switches, sliding switches (e.g., touch-sensor slider), and touch-sensor pads implemented as a pair of orthogonal sliding switches. The CSR may include physical, electrical, and software components. The physical component may include the physical switch itself, typically a pattern constructed on a printed circuit board (PCB) with an insulating cover, a flexible membrane, or a transparent overlay. The electrical component may include an oscillator or other means to convert a changed capacitance into a measured signal. The electrical component may also include a counter or timer to measure the oscillator output. The software component may include detection and compensation software algorithms to convert the count value into a switch detection decision. For example, in the case of slide switches or X-Y touch-sensor pads, a calculation for finding position of the conductive object to greater resolution than the physical pitch of the switches may be used.

It should be noted that there are various known methods for measuring capacitance. Although the embodiments described herein are described using a relaxation oscillator, the present embodiments are not limited to using relaxation oscillators, but may include other methods, such as current versus voltage phase shift measurement, resistor-capacitor charge timing, capacitive bridge divider or, charge transfer.

The current versus voltage phase shift measurement may include driving the capacitance through a fixed-value resistor to yield voltage and current waveforms that are out of phase by a predictable amount. The drive frequency can be adjusted to keep the phase measurement in a readily measured range. The resistor-capacitor charge timing may include charging the capacitor through a fixed resistor and measuring timing on the voltage ramp. Small capacitor values may require very large resistors for reasonable timing. The capacitive bridge divider may include driving the capacitor under test through a fixed reference capacitor. The reference capacitor and the capacitor under test form a voltage divider. The voltage signal is recovered with a synchronous demodulator, which may be done in the processing device 210. The charge transfer may be conceptually similar to an R-C charging circuit. In this method, C_{P} is the capacitance being sensed. C_{SUM} is the summing capacitor, into which charge is transferred on successive cycles. At the start of the measurement cycle, the voltage on C_{SUM} is reset. The voltage on C_{SUM} increases exponentially (and only slightly) with each clock cycle. The time for this voltage to reach a specific threshold is measured with a counter. Additional details regarding these alternative embodiments have not been included so as to not obscure the present embodiments, and because these alternative embodiments for measuring capacitance are known by those of ordinary skill in the art.

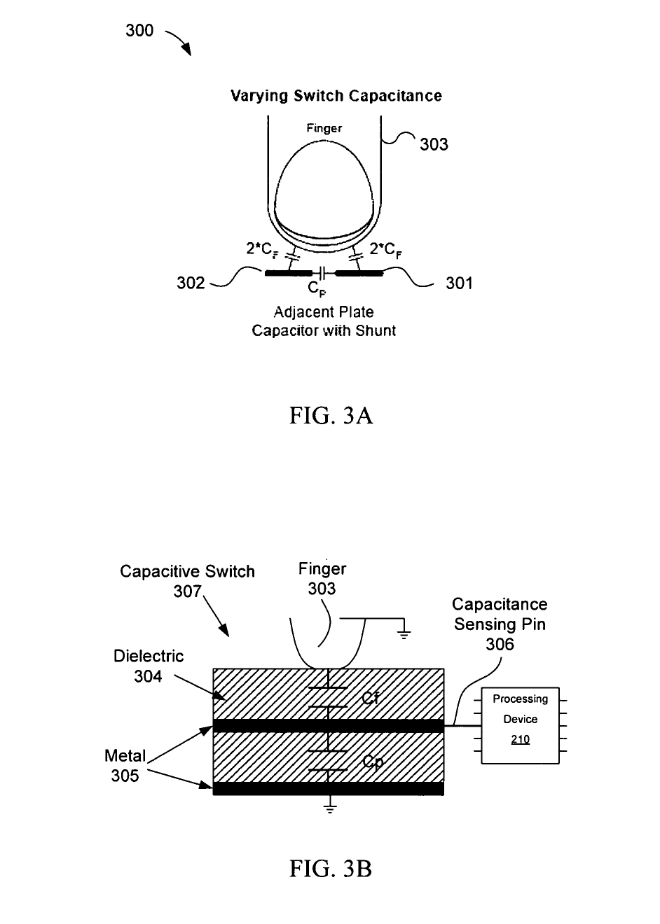

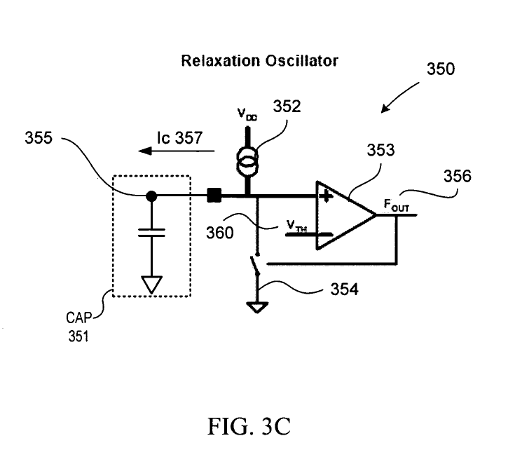

FIG. 3A illustrates a varying switch capacitance. In its basic form, a capacitive switch 300 is a pair of adjacent plates 301 and 302. There is a small edge-to-edge capacitance Cp, but the intent of switch layout is to minimize the base capacitance Cp between these plates. When a conductive object 303 (e.g., finger) is placed in proximity to the two plate 301 and 302, there is a capacitance 2*Cf between one electrode 301 and the conductive object 303 and a similar capacitance 2*Cf between the conductive object 303 and the other electrode 302. The capacitance between one electrode 301 and the conductive object 303 and back to the other electrode 302 adds in parallel to the base capacitance Cp between the plates 301 and 302, resulting in a change of capacitance Cf. Capacitive switch 300 may be used in a capacitance switch array. The capacitance switch array is a set of capacitors where one side of each is grounded. Thus, the active capacitor (as represented in FIG. 3C as capacitor 351) has only one accessible side. The presence of the conductive object 303 increases the capacitance (Cp+Cf) of the switch 300 to ground. Determining switch activation is then a matter of measuring change in the capacitance (Cf). Switch 300 is also known as a grounded variable capacitor. In one exemplary embodiment, Cf may range from approximately 10-30 picofarads (pF). Alternatively, other ranges may be used.

The conductive object in this case is a finger, alternatively, this technique may be applied to any conductive object, for example, a conductive door switch, position sensor, or conductive pen in a stylus tracking system.

FIG. 3B illustrates one embodiment of a capacitive switch 307 coupled to a processing device 210. Capacitive switch 307 illustrates the capacitance as seen by the processing device 210 on the capacitance sensing pin 306. As described above, when a conductive object 303 (e.g., finger) is placed in proximity to one of the metal plates 305, there is a capacitance, Cf, between the metal plate and the conductive object 303 with respect to ground. Also, there is a capacitance, Cp, between the two metal plates. Accordingly, the processing device 210 can measure the change in capacitance, capacitance variation Cf, as the conductive object is in proximity to the metal plate 305. Above and below the metal plate that is closest to the conductive object 303 is dielectric material 304. The dielectric material 304 above the metal plate 305 can be the overlay, as described in more detail below. The overlay may be non-conductive material used to protect the circuitry to environmental elements and to insulate the user's finger (e.g., conductive object) from the circuitry. Capacitance switch 307 may be a sensor element of a touch-sensor pad, a touch-sensor slider, or a touch-sensor button.

FIG. 3C illustrates one embodiment of a relaxation oscillator. The relaxation oscillator 350 is formed by the capacitance to be measured on capacitor 351, a charging current source 352, a comparator 353, and a reset switch 354. It should be noted that capacitor 351 is representative of the capacitance measured on a sensor element of a sensor array. The relaxation oscillator is coupled to drive a charging current (Ic) 357 in a single direction onto a device under test (“DUT”) capacitor, capacitor 351. As the charging current piles charge onto the capacitor 351, the voltage across the capacitor increases with time as a function of Ic 357 and its capacitance C. Equation (10) describes the relation between current, capacitance, voltage and time for a charging capacitor.

CdV=I_{c}dt (10)

The relaxation oscillator begins by charging the capacitor 351 from a ground potential or zero voltage and continues to pile charge on the capacitor 351 at a fixed charging current Ic 357 until the voltage across the capacitor 351 at node 355 reaches a reference voltage or threshold voltage, V_{TH} 360 At the threshold voltage V_{TH} 360 the relaxation oscillator allows the accumulated charge at node 355 to discharge (e.g., the capacitor 351 to “relax” back to the ground potential) and then the process repeats itself. In particular, the output of comparator 353 asserts a clock signal F_{OUT} 356 (e.g., F_{OUT} 356 goes high), which enables the reset switch 354. This resets the voltage on the capacitor at node 355 to ground and the charge cycle starts again. The relaxation oscillator outputs a relaxation oscillator clock signal (F_{OUT} 356) having a frequency (f_{Ro}) dependent upon capacitance C of the capacitor 351 and charging current Ic 357.

The comparator trip time of the comparator 353 and reset switch 354 add a fixed delay. The output of the comparator 353 is synchronized with a reference system clock to guarantee that the comparator reset time is long enough to completely reset the charging voltage on capacitor 351 This sets a practical upper limit to the operating frequency. For example, if capacitance C of the capacitor 351 changes, then f_{RO} will change proportionally according to Equation (2). By comparing f_{RO} of F_{OUT} 356 against the frequency (f_{REF}) of a known reference system clock signal (REF CLK), the change in capacitance ΔC can be measured. Accordingly, equations (11) and (12) below describe that a change in frequency between F_{OUT} 356 and REF CLK is proportional to a change in capacitance of the capacitor 351.

ΔC∝Δf, where (11)

Δf=f_{RO}−f_{REF}. (12)

In one embodiment, a frequency comparator may be coupled to receive relaxation oscillator clock signal (F_{OUT} 356) and REF CLK, compare their frequencies f_{RO} and f_{REF}, respectively, and output a signal indicative of the difference Δf between these frequencies. By monitoring Δf one can determine whether the capacitance of the capacitor 351 has changed.

In one exemplary embodiment, the relaxation oscillator 350 may be built using a programmable timer (e.g., 555 timer) to implement the comparator 353 and reset switch 354. Alternatively, the relaxation oscillator 350 may be built using other circuiting. Relaxation oscillators are known by those of ordinary skill in the art, and accordingly, additional details regarding their operation have not been included so as to not obscure the present embodiments.

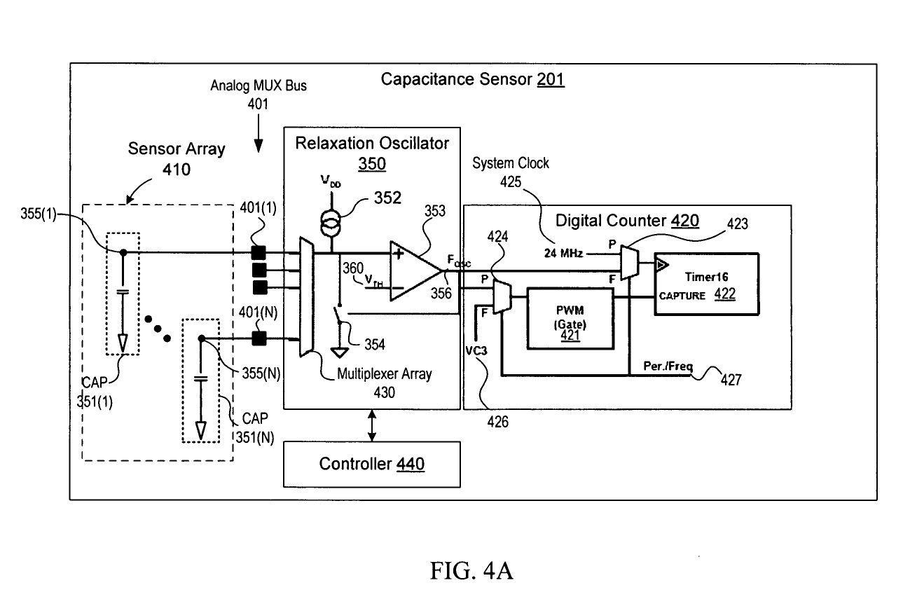

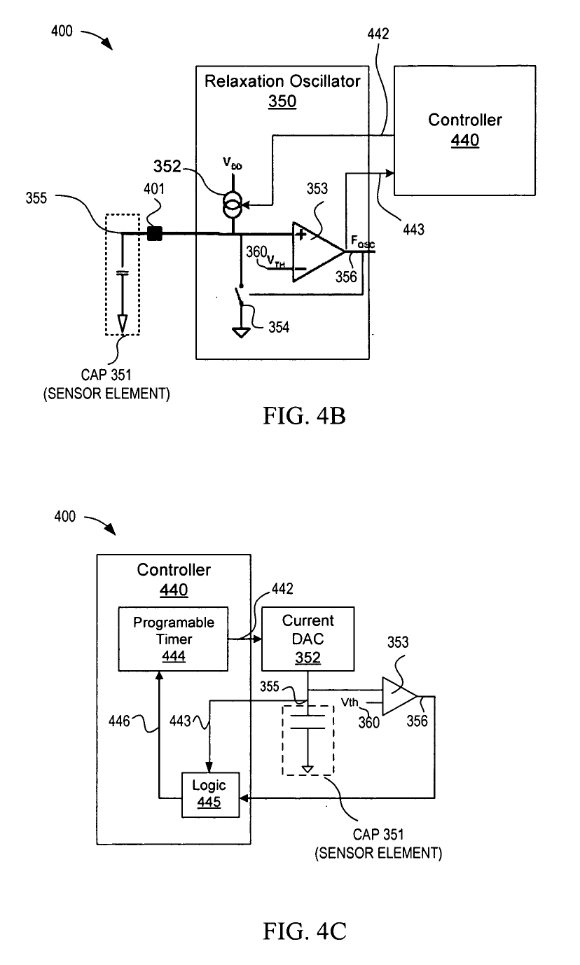

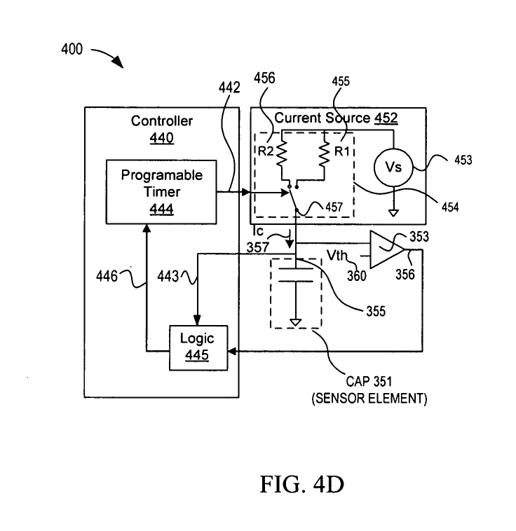

FIG. 4A illustrates a block diagram of one embodiment of a capacitance sensor including a relaxation oscillator, a controller, and digital counter. Capacitance sensor 201 of FIG. 4A includes a sensor array 410 (also known as a switch array), relaxation oscillator 350, and a digital counter 420. Sensor array 410 includes a plurality of sensor elements 355(1)-355(N), where N is a positive integer value that represents the number of rows (or alternatively columns) of the sensor array 410. Each sensor element is represented as a capacitor, as previously described with respect to FIG. 3C. The sensor array 410 is coupled to relaxation oscillator 350 via an analog bus 401 having a plurality of pins 401(1)-401(N). In one embodiment, the sensor array 410 may be a single-dimension sensor array including the sensor elements 355(1)-355(N), where N is a positive integer value that represents the number of sensor elements of the single-dimension sensor array. The single-dimension sensor array 410 provides output data to the analog bus 401 of the processing device 210 (e.g., via lines 231). Alternatively, the sensor array 410 may be a multi-dimension sensor array including the sensor elements 355(1)-355(N), where N is a positive integer value that represents the number of sensor elements of the multi-dimension sensor array. The multi-dimension sensor array 410 provides output data to the analog bus 401 of the processing device 210 (e.g., via bus 221).

Relaxation oscillator 350 of FIG. 4A includes all the components described with respect to FIG. 3C, and a selection circuit 430. The selection circuit 430 is coupled to the plurality of sensor elements 355(1)-355(N), the reset switch 354, the current source 352, and the comparator 353. Selection circuit 430 may be used to allow the relaxation oscillator 350 to measure capacitance on multiple sensor elements (e.g., rows or columns). The selection circuit 430 may be configured to sequentially select a sensor element of the plurality of sensor elements to provide the charging current and to measure the capacitance of each sensor element. In one exemplary embodiment, the selection circuit 430 is a multiplexer array of the relaxation oscillator 350. Alternatively, selection circuit may be other circuitry outside the relaxation oscillator 350, or even outside the capacitance sensor 201 to select the sensor element to be measured. Capacitance sensor 201 may include one relaxation oscillator and digital counter for the plurality of sensor elements of the sensor array. Alternatively, capacitance sensor 201 may include multiple relaxation oscillators and digital counters to measure capacitance on the plurality of sensor elements of the sensor array. The multiplexer array may also be used to ground the sensor elements that are not being measured. This may be done in conjunction with a dedicated pin in the GP 10 port 207.

In another embodiment, the capacitance sensor 201 may be configured to simultaneously scan the sensor elements, as opposed to being configured to sequentially scan the sensor elements as described above. For example, the sensing device may include a sensor array having a plurality of rows and columns. The rows may be scanned simultaneously, and the columns may be scanned simultaneously.

In one exemplary embodiment, the voltages on all of the rows of the sensor array are simultaneously moved, while the voltages of the columns are held at a constant voltage, with the complete set of sampled points simultaneously giving a profile of the conductive object in a first dimension. Next, the voltages on all of the rows are held at a constant voltage, while the voltages on all the rows are simultaneously moved, to obtain a complete set of sampled points simultaneously giving a profile of the conductive object in the other dimension.

In another exemplary embodiment, the voltages on all of the rows of the sensor array are simultaneously moved in a positive direction, while the voltages of the columns are moved in a negative direction. Next, the voltages on all of the rows of the sensor array are simultaneously moved in a negative direction, while the voltages of the columns are moved in a positive direction. This technique doubles the effect of any transcapacitance between the two dimensions, or conversely, halves the effect of any parasitic capacitance to the ground. In both methods, the capacitive information from the sensing process provides a profile of the presence of the conductive object to the sensing device in each dimension. Alternatively, other methods for scanning known by those of ordinary skill in the art may be used to scan the sensing device.

Digital counter 420 is coupled to the output of the relaxation oscillator 350. Digital counter 420 receives the relaxation oscillator output signal 356 (F_{OUT}). Digital counter 420 is configured to count at least one of a frequency or a period of the relaxation oscillator output received from the relaxation oscillator.

As previously described with respect to the relaxation oscillator 350, when a finger or conductive object is placed on the switch, the capacitance increases from Cp to Cp+Cf so the relaxation oscillator output signal 356 (F_{OUT}) decreases. The relaxation oscillator output signal 356 (F_{OUT}) is fed to the digital counter 420 for measurement. There are two methods for counting the relaxation oscillator output signal 356, frequency measurement and period measurement. In one embodiment, the digital counter 420 may include two multiplexers 423 and 424. Multiplexers 423 and 424 are configured to select the inputs for the PWM 421 and the timer 422 for the two measurement methods, frequency and period measurement methods. Alternatively, other selection circuits may be used to select the inputs for the PWM 421 and the time 422. In another embodiment, multiplexers 423 and 424 are not included in the digital counter, for example, the digital counter 420 may be configured in one, or the other, measurement configuration.

In the frequency measurement method, the relaxation oscillator output signal 356 is counted for a fixed period of time. The counter 422 is read to obtain the number of counts during the gate time. This method works well at low frequencies where the oscillator reset time is small compared to the oscillator period. A pulse width modulator (PWM) 421 is clocked for a fixed period by a derivative of the system clock, VC3 426 (which is a divider from system clock 425, e.g., 24 MHz). Pulse width modulation is a modulation technique that generates variable-length pulses to represent the amplitude of an analog input signal; in this case VC3 426. The output of PWM 421 enables timer 422 (e.g., 16-bit). The relaxation oscillator output signal 356 clocks the timer 422. The timer 422 is reset at the start of the sequence, and the count value is read out at the end of the gate period.

In the period measurement method, the relaxation oscillator output signal 356 gates a counter 422, which is clocked by the system clock 425 (e.g., 24 MHz). In order to improve sensitivity and resolution, multiple periods of the oscillator are counted with the PWM 421. The output of PWM 421 is used to gate the timer 422. In this method, the relaxation oscillator output signal 356 drives the clock input of PWM 421. As previously described, pulse width modulation is a modulation technique that generates variable-length pulses to represent the amplitude of an analog input signal; in this case the relaxation oscillator output signal 356. The output of the PWM 421 enables timer 422 (e.g., 16-bit), which is clocked at the system clock frequency 425 (e.g., 24 MHz). When the output of PWM 421 is asserted (e.g., goes high), the count starts by releasing the capture control. When the terminal count of the PWM 421 is reached, the capture signal is asserted (e.g., goes high), stopping the count and setting the PWM's interrupt. The timer value is read in this interrupt. The relaxation oscillator 350 is indexed to the next switch (e.g., capacitor 351(2)) to be measured and the count sequence is started again.

The two counting methods may have equivalent performance in sensitivity and signal-to-noise ratio (SNR). The period measurement method may have a slightly faster data acquisition rate, but this rate is dependent on software loads and the values of the switch capacitances. The frequency measurement method has a fixed-switch data acquisition rate.

The length of the counter 422 and the detection time required for the switch are determined by sensitivity requirements. Small changes in the capacitance on capacitor 351 result in small changes in frequency. In order to find these small changes, it may be necessary to count for a considerable time.

At startup (or boot) the switches (e.g., capacitors 351(1)-(N)) are scanned and the count values for each switch with no actuation are stored as a baseline array (Cp). The presence of a finger on the switch is determined by the difference in counts between a stored value for no switch actuation and the acquired value with switch actuation, referred to here as Δn. The sensitivity of a single switch is approximately:

$$\frac{Δ n}{n} = \frac{Cf}{Cp} \qquad ( 13 )$$

The value of Δn should be large enough for reasonable resolution and clear indication of switch actuation. This drives switch construction decisions.

Cf should be as large a fraction of Cp as possible. In one exemplary embodiment, the fraction of Cf/Cp ranges between approximately 0.01 to approximately 2.0. Alternatively, other fractions may be used for Cf/Cp. Since Cf is determined by finger area and distance from the finger to the switch's conductive traces (through the over-lying insulator), the baseline capacitance Cp should be minimized. The baseline capacitance Cp includes the capacitance of the switch pad plus any parasitics, including routing and chip pin capacitance.

FIG. 4A also illustrates the capacitance sensor 201 that has controller 440 coupled to the relaxation oscillator 350. The controller 440 is operable to control the charging current (Ic) 357 that is provided to the sensor elements (e.g., 351(1)-351(N)) of the sensor array 410. For example, controller 440 may change a first charging rate to a second charging rate, which is higher than the first charging rate. Controller 440 may be used to increase and/or decrease the amount of current that is supplied to the sensor element, modifying the charging rates and/or the discharging rates of the sensor element.

FIG. 4B illustrates a block diagram of one embodiment of a dual-slope charging relaxation oscillator having a relaxation oscillator and a controller. Dual-slope charging relaxation oscillator 400 includes relaxation oscillator 350 and controller 440. Relaxation oscillator 350 includes similar elements as the relaxation oscillator 350 described with respect to FIG. 4A. Controller 440 is coupled to relaxation oscillator 350 through control line 442 and feedback line 443. Controller 440 controls the charge rates for charging current source 352. For example, using control line 442, controller 440 sets charging current source 352 at a first charging rate for a fixed time, and then changes the charging current source 352 to a second charging rate to reach the threshold voltage V_{TH} 360 after the sensor element has been charged for the fixed time. Alternatively, controller 440 uses control line 442 to set discharging rates of the relaxation oscillator 350.

In one embodiment, the controller 440 receives information on feedback line 443 from relaxation oscillator 350. Feedback line 443 may provide voltage information on the output of the comparator (e.g., clock signal F_{OUT} 356). This information may be used to control when the sensor element has been charged to the voltage threshold V_{TH} 360.

FIG. 4C illustrates a block diagram of one embodiment of a controller of a dual-slope charging relaxation oscillator. Controller 440 of FIG. 4C includes programmable timer 444, and logic circuit 445. Programmable timer 444 may be programmed to change the charging and/or discharging rates of the dual-slope relaxation oscillator 400 at a fixed time. In another embodiment, controller 440 may be hard-wired to provide the fixed time. Logic circuit 445 receives feedback from the relaxation oscillator on feedback line 443. Logic circuit 445 may be used to control the programmable timer 444 using control line 446. For example, logic circuit 445 may signal to the programmable timer 444, on line 446, when the threshold voltage V_{TH} 360 has been reached on the sensor element 351.

The programmable timer 444 and logic circuit 445 of controller 440 may be used to charge or discharge the sensor element 351 at different charge rates. For example, the controller 440 may use two different charging rates and one discharging rate. Alternatively, the controller 440 may use two different discharging rates and one charging rate, or two different charging rates and two different discharging rates.

In one embodiment, the fixed time is programmable. Alternatively, the fixed time may be pre-determined and hardwired into the controller 440. Similarly, the threshold voltage V_{TH} 360 may be programmable, or pre-determined and hardwired into controller 440.

In one embodiment, the controller 440 may be programmed to control the current source 352 to provide linear charging rates. Alternatively, the charging rates may be exponential, or programmed to have a pre-determined charge response. For example, the first charge rate of the current source 352 may be linear for a fixed time, and then after the fixed time the controller 440 controls the current source 352 to change to a second charge rate, which is also linear, but at a slower rate than the first charge rate, until the voltage threshold V_{TH} 360 is reached. Another example includes charging the sensor element at an exponential charge rate for a fixed time, and then charging the sensor element at a linear charge rate until the voltage threshold V_{TH} 360 is reached. In other words, the embodiments of the charge and discharge rates for charging and discharging the sensor element are not limited to linear rates, but may be non-linear rates.

The current source 352 of FIG. 4C is a current DAC. The current DAC may be a register programmable current output DAC (also known as IDAC). The IDAC output current may be set by an 8-bit value provided by the processing device 210, such as from the processing core 202. The 8-bit value may be stored in a register or in memory. Alternatively, other circuits may be used to provide current to the sensor element, for example, a constant voltage source and resistor, as described in FIG. 4D.

In one embodiment, the current DAC 352 is configured to generate both positive and negative currents (both source and sink). Accordingly, controller 440 may control both the charge and discharge rates of capacitor 351 (e.g., sensor element) using the current DAC 352. In another embodiment, the relaxation oscillator 350 is configured to discharge the capacitor 351 (e.g., sensor element) using an on/off reset switch. Alternatively, the discharge rates may be controlled using other circuits known by those of ordinary skill in the art. For example, current source 452 may be complemented with an additional current source sinking to ground to discharge capacitor 351. The additional current source may be controlled by controller 440 to control the discharge rate of the capacitor 351.

FIG. 4D illustrates a block diagram of another embodiment of a controller of a dual-slope charging relaxation oscillator. Dual-slope charging relaxation oscillator 400 of FIG. 4D includes the same components as the dual-slope charging relaxation oscillator 400 of FIG. 4C, except the current source. Current source 452 is coupled to the controller 440, and to the rest of the components of the relaxation oscillator 350. In particular, the controller 440 provides control signals to the current source 452 on control line 442 (e.g., from programmable timer 444), and the current source 452 provides feedback signals to the controller 440 on feedback line 443 (e.g., to logic circuit 445). Current source 452 includes constant voltage source 453 and resistor circuit 454. Constant voltage source 453 provides a constant voltage to the resistor circuit 454, which generates a charging current (Ic) 357 to capacitor 351 (e.g., sensor element). Controller 440 may control resistor circuit 454 to change its resistance in order to change the charging current 357. For example, in one embodiment, the resistor circuit 454 may include two resistors 455 and 456, and a switch 457. When the fixed time has passed, the controller 440 signals to have the resistor circuit 454 switch from one resistor 455 to another lower-valued resistor 456 using switch 457. This effectively, lowers the current generated by the current source 452. Alternatively, other configurations of the constant voltage source 453 and the resistor circuit 454 may be used to charge the capacitor 351 at one or more charging rates.

It should be noted that the embodiments of a dual-slope relaxation oscillator, having a controller and a current source to charge the capacitor 351, are not limited to the configurations described with respect to FIGS. 4A-4D, but may include other configurations that permit the sensor element to be charged at one rate for a fixed amount of time, and at another rate until the voltage threshold is reached.

In switch array applications, variations in sensitivity should be minimized. If there are large differences in Δn, one switch may actuate at 1.0 cm, while another may not actuate until direct contact. This presents a non-ideal user interface device. There are numerous methods for balancing the sensitivity. These may include precisely matching on-board capacitance with PC trace length modification, adding balance capacitors on each switch's PC board trace, and/or adapting a calibration factor to each switch to be applied each time the switch is tested.

In one embodiment, the PCB design may be adapted to minimize capacitance, including thicker PCBs where possible. In one exemplary embodiment, a 0.062 inch thick PCB is used. Alternatively, other thicknesses may be used, for example, a 0.015 inch thick PCB.

It should be noted that the count window should be long enough for Δn to be a “significant number.” In one embodiment, the “significant number” can be as little as 10, or alternatively, as much as several hundred. In one exemplary embodiment, where Cf is 1.0% of Cp (a typical “weak” switch), and where the switch threshold is set at a count value of 20, n is found to be:

$$n = Δ n \cdot \frac{Cf}{Cp} = 2000 \qquad ( 14 )$$

Adding some margin to yield 2500 counts, and running the frequency measurement method at 1.0 MHz, the detection time for the switch is 4 microseconds. In the frequency measurement method, the frequency difference between a switch with and without actuation (i.e., CP+CF vs. CP) is approximately:

$$Δ n = \frac{{t}_{count} \cdot {i}_{c}}{{V}_{TH}} \frac{Cf}{{Cp}^{2}} \qquad ( 15 )$$

This shows that the sensitivity variation between one channel and another is a function of the square of the difference in the two channels' static capacitances. This sensitivity difference can be compensated using routines in the high-level Application Programming Interfaces (APIs).

In the period measurement method, the count difference between a switch with and without actuation (i.e., CP+CF vs. CP) is approximately:

$$Δ n = {N}_{Periods} \cdot \frac{Cf \cdot {V}_{TH}}{{i}_{C}} \cdot {f}_{SysClk} \qquad ( 16 )$$

The charging currents are typically lower and the period is longer to increase sensitivity, or the number of periods for which f_{SysClk} is counted can be increased. In either method, by matching the static (parasitic) capacitances Cp of the individual switches, the repeatability of detection increases, making all switches work at the same difference. Compensation for this variation can be done in software at runtime. The compensation algorithms for both the frequency method and period method may be included in the high-level APIs.

Some implementations of this circuit use a current source programmed by a fixed-resistor value. If the range of capacitance to be measured changes, external components, (i.e., the resistor) should be adjusted.

Using the multiplexer array 430, multiple sensor elements may be sequentially scanned to provide current to and measure the capacitance from the capacitors (e.g., sensor elements), as previously described. In other words, while one sensor element is being measured, the remaining sensor elements are grounded using the GPIO port 207. This drive and multiplex arrangement bypasses the existing GPIO to connect the selected pin to an internal analog multiplexer (mux) bus. The capacitor charging current (e.g., current source 352) and reset switch 354 are connected to the analog mux bus. This may limit the pin-count requirement to simply the number of switches (e.g., capacitors 351(1)-351(N)) to be addressed. In one exemplary embodiment, no external resistors or capacitors are required inside or outside the processing device 210 to enable operation.

The capacitor charging current for the relaxation oscillator 350 is generated in a register programmable current output DAC (also known as IDAC). Accordingly, the current source 352 is a current DAC or IDAC. The IDAC output current may be set by an 8-bit value provided by the processing device 210, such as from the processing core 202. The 8-bit value may be stored in a register or in memory.

Estimating and measuring PCB capacitances may be difficult; the oscillator-reset time may add to the oscillator period (especially at higher frequencies); and there may be some variation to the magnitude of the IDAC output current with operating frequency. Accordingly, the optimum oscillation frequency and operating current for a particular switch array may be determined to some degree by experimentation.

In many capacitive switch designs the two “plates” (e.g., 301 and 302) of the sensing capacitor are actually adjacent sensor elements that are electrically isolated (e.g., PCB pads or traces), as indicated in FIG. 3A. Typically, one of these plates is grounded. Layouts for touch-sensor slider (e.g., linear slide switches) and touch-sensor pad applications have switches that are immediately adjacent. In this case, all of the switches that are not active are grounded through the GPIO 207 of the processing device 210 dedicated to that pin. The actual capacitance between adjacent plates is small (Cp), but the capacitance of the active plate (and its PCB trace back to the processing device 210) to ground, when detecting the presence of the conductive object 303, may be considerably higher (Cp+Cf). The capacitance of two parallel plates is given by the following equation:

$$C = {ɛ}_{0} \cdot {ɛ}_{R} \cdot \frac{A}{d} = {ɛ}_{R} \cdot 8.85 \cdot \frac{A}{d} pF / m \qquad ( 17 )$$

The dimensions of equation (17) are in meters. This is a very simple model of the capacitance. The reality is that there are fringing effects that substantially increase the switch-to-ground (and PCB trace-to-ground) capacitance.

Switch sensitivity (i.e., actuation distance) may be increased by one or more of the following: 1) increasing board thickness to increase the distance between the active switch and any parasitics; 2) minimizing PC trace routing underneath switches; 3) utilizing a grided ground with 50% or less fill if use of a ground plane is absolutely necessary; 4) increasing the spacing between switch pads and any adjacent ground plane; 5) increasing pad area; 6) decreasing thickness of any insulating overlay; or 7) verifying that there is no air-gap between the PC pad surface and the touching finger.

There is some variation of switch sensitivity as a result of environmental factors. A baseline update routine, which compensates for this variation, may be provided in the high-level APIs.

Sliding switches are used for control requiring gradual adjustments. Examples include a lighting control (dimmer), volume control, graphic equalizer, and speed control. These switches are mechanically adjacent to one another. Actuation of one switch results in partial actuation of physically adjacent switches. The actual position in the sliding switch is found by computing the centroid location of the set of switches activated.

In applications for touch-sensor sliders (e.g., sliding switches) and touch-sensor pads it is often necessary to determine finger (or other capacitive object) position to more resolution than the native pitch of the individual switches. The contact area of a finger on a sliding switch or a touch-pad is often larger than any single switch. In one embodiment, in order to calculate the interpolated position using a centroid, the array is first scanned to verify that a given switch location is valid. The requirement is for some number of adjacent switch signals to be above a noise threshold. When the strongest signal is found, this signal and those immediately adjacent are used to compute a centroid:

$$Centroid = \frac{{n}_{i - 1} \cdot ( i - 1 ) + {n}_{i} i + {n}_{i + 1} \cdot ( i + 1 )}{{n}_{i - 1} + {n}_{i} i + {n}_{i + 1}} \qquad ( 18 )$$

The calculated value will almost certainly be fractional. In order to report the centroid to a specific resolution, for example a range of 0 to 100 for 12 switches, the centroid value may be multiplied by a calculated scalar. It may be more efficient to combine the interpolation and scaling operations into a single calculation and report this result directly in the desired scale. This may be handled in the high-level APIs. Alternatively, other methods may be used to interpolate the position of the conductive object.

A physical touchpad assembly is a multi-layered module to detect a conductive object. In one embodiment, the multi-layer stack-up of a touchpad assembly includes a PCB, an adhesive layer, and an overlay. The PCB includes the processing device 210 and other components, such as the connector to the host 250, necessary for operations for sensing the capacitance. These components are on the non-sensing side of the PCB. The PCB also includes the sensor array on the opposite side, the sensing side of the PCB. Alternatively, other multi-layer stack-ups may be used in the touchpad assembly.

The PCB may be made of standard materials, such as FR4 or Kapton™ (e.g., flexible PCB). In either case, the processing device 210 may be attached (e.g., soldered) directly to the sensing PCB (e.g., attached to the non-sensing side of the PCB). The PCB thickness varies depending on multiple variables, including height restrictions and sensitivity requirements. In one embodiment, the PCB thickness is at least approximately 0.3 millimeters (mm). Alternatively, the PCB may have other thicknesses. It should be noted that thicker PCBs may yield better results. The PCB length and width is dependent on individual design requirements for the device on which the sensing device is mounted, such as a notebook or mobile handset.

The adhesive layer is directly on top of the PCB sensing array and is used to affix the overlay to the overall touchpad assembly. Typical material used for connecting the overlay to the PCB is non-conductive adhesive such as 3M 467 or 468. In one exemplary embodiment, the adhesive thickness is approximately 0.05 mm. Alternatively, other thicknesses may be used.

The overlay may be non-conductive material used to protect the PCB circuitry to environmental elements and to insulate the user's finger (e.g., conductive object) from the circuitry. Overlay can be ABS plastic, polycarbonate, glass, or Mylar™. Alternatively, other materials known by those of ordinary skill in the art may be used. In one exemplary embodiment, the overlay has a thickness of approximately 1.0 mm. In another exemplary embodiment, the overlay thickness has a thickness of approximately 2.0 mm. Alternatively, other thicknesses may be used.

The sensor array may be a grid-like pattern of sensor elements (e.g., capacitive elements) used in conjunction with the processing device 210 to detect a presence of a conductive object, such as finger, to a resolution greater than that which is native. The touch-sensor pad layout pattern maximizes the area covered by conductive material, such as copper, in relation to spaces necessary to define the rows and columns of the sensor array.

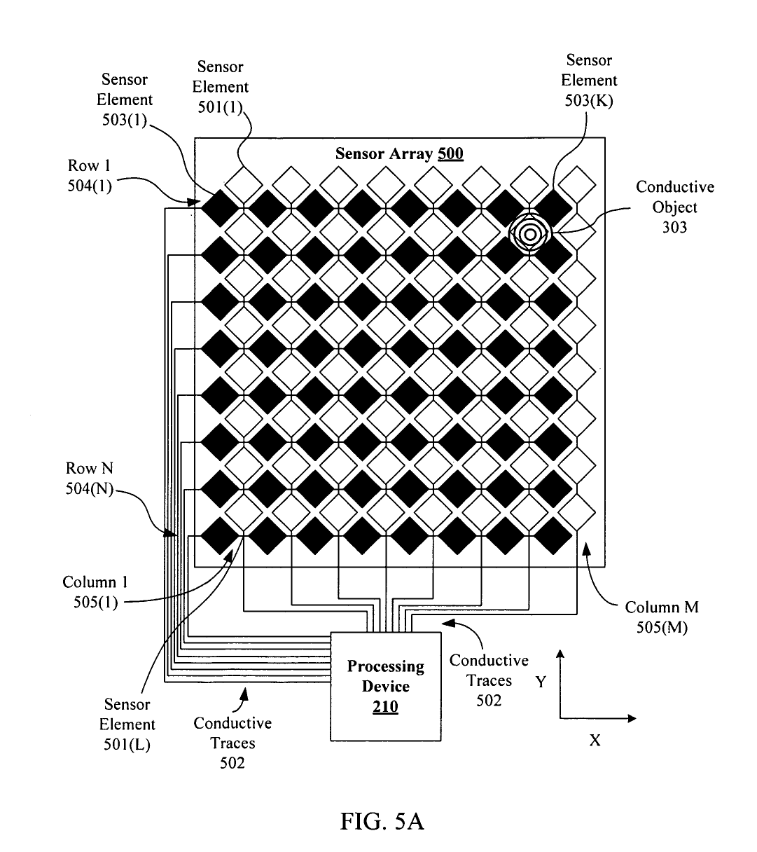

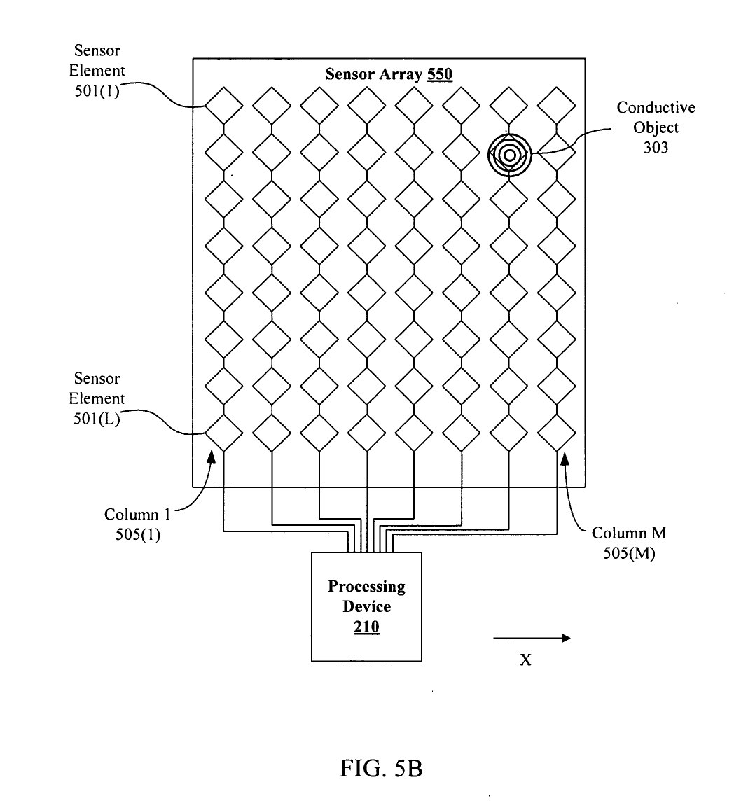

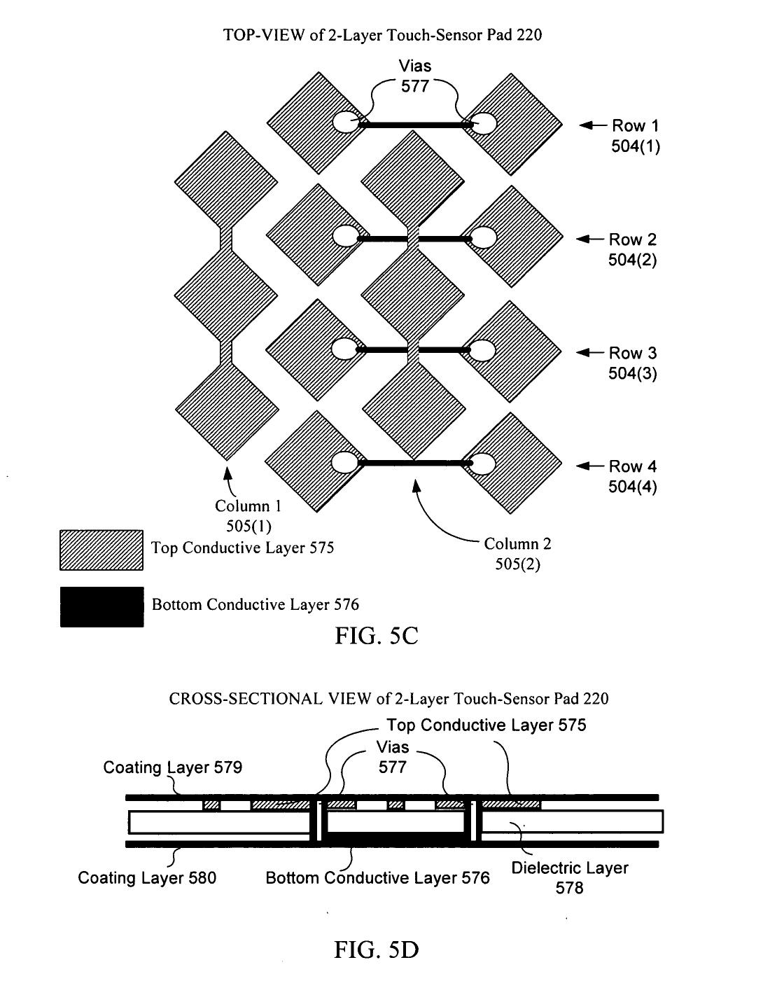

FIG. 5A illustrates a top-side view of one embodiment of a sensor array having a plurality of sensor elements for detecting a presence of a conductive object 303 on the sensor array 500 of a touch-sensor pad. Touch-sensor pad 220 includes a sensor array 500. Sensor array 500 includes a plurality of rows 504(1)-504(N) and a plurality of columns 505(1)-505(M), where N is a positive integer value representative of the number of rows and M is a positive integer value representative of the number of columns. Each row includes a plurality of sensor elements 503(1)-503(K), where K is a positive integer value representative of the number of sensor elements in the row. Each column includes a plurality of sensor elements 501(1)-501(L), where L is a positive integer value representative of the number of sensor elements in the column. Accordingly, sensor array is an N×M sensor matrix. The N×M sensor matrix, in conjunction with the processing device 210, is configured to detect a position of a presence of the conductive object 303 in the x-, and y-directions.

FIG. 5B illustrates a top-side view of one embodiment of a sensor array having a plurality of sensor elements for detecting a presence of a conductive object 303 on the sensor array 550 of a touch-sensor slider. Touch-sensor slider 230 includes a sensor array 550. Sensor array 550 includes a plurality of columns 504(1)-504(M), where M is a positive integer value representative of the number of columns. Each column includes a plurality of sensor elements 501(1)-501(L), where L is a positive integer value representative of the number of sensor elements in the column. Accordingly, sensor array is a 1×M sensor matrix. The 1×M sensor matrix, in conjunction with the processing device 210, is configured to detect a position of a presence of the conductive object 303 in the x-direction. It should be noted that sensor array 500 may be configured to function as a touch-sensor slider 230.

Alternating columns in FIG. 5A correspond to x- and y-axis elements. The y-axis sensor elements 503(1)-503(K) are illustrated as black diamonds in FIG. 5A, and the x-axis sensor elements 501(1)-501(L) are illustrated as white diamonds in FIG. 5A and FIG. 5B. It should be noted that other shapes may be used for the sensor elements. In another embodiment, the columns and row may include vertical and horizontal bars (e.g., rectangular shaped bars); however, this design may include additional layers in the PCB to allow the vertical and horizontal bars to be positioned on the PCB so that they are not in contact with one another.

FIGS. 5C and 5D illustrate top-side and side views of one embodiment of a two-layer touch-sensor pad. Touch-sensor pad, as illustrated in FIGS. 5C and 5D, include the first two columns 505(1) and 505(2), and the first four rows 504(1)-504(4) of sensor array 500. The sensor elements of the first column 501(1) are connected together in the top conductive layer 575, illustrated as hashed diamond sensor elements and connections. The diamond sensor elements of each column, in effect, form a chain of elements. The sensor elements of the second column 501(2) are similarly connected in the top conductive layer 575. The sensor elements of the first row 504(1) are connected together in the bottom conductive layer 576 using vias 577, illustrated as black diamond sensor elements and connections. The diamond sensor elements of each row, in effect, form a chain of elements. The sensor elements of the second, third, and fourth rows 504(2)-504(4) are similarly connected in the bottom conductive layer 576.

As illustrated in FIG. 5D, the top conductive layer 575 includes the sensor elements for both the columns and the rows of the sensor array, as well as the connections between the sensor elements of the columns of the sensor array. The bottom conductive layer 576 includes the conductive paths that connect the sensor elements of the rows that reside in the top conductive layer 575. The conductive paths between the sensor elements of the rows use vias 577 to connect to one another in the bottom conductive layer 576. Vias 577 go from the top conductive layer 575, through the dielectric layer 578, to the bottom conductive layer 576. Coating layers 579 and 580 are applied to the surfaces opposite to the surfaces that are coupled to the dielectric layer 578 on both the top and bottom conductive layers 575 and 576.

It should be noted that the space between coating layers 579 and 580 and dielectric layer 578, which does not include any conductive material, may be filled with the same material as the coating layers or dielectric layer. Alternatively, it may be filled with other materials.

It should be noted that the present embodiments are not be limited to connecting the sensor elements of the rows using vias to the bottom conductive layer 576, but may include connecting the sensor elements of the columns using vias to the bottom conductive layer 576. Furthermore, the present embodiments are not limited two-layer configurations, but may include disposing the sensor elements on multiple layers, such as three- or four-layer configurations.

When pins are not being sensed (only one pin is sensed at a time), they are routed to ground. By surrounding the sensing device (e.g., touch-sensor pad) with a ground plane, the exterior elements have the same fringe capacitance to ground as the interior elements.

In one embodiment, an IC including the processing device 210 may be directly placed on the non-sensor side of the PCB. This placement does not necessary have to be in the center. The processing device IC is not required to have a specific set of dimensions for a touch-sensor pad, nor a certain number of pins. Alternatively, the IC may be placed somewhere external to the PCB.

FIG. 6A illustrates a graph of one embodiment of the voltage on sensor element with respect to time as the capacitor is charged to the threshold voltage using the dual-slope charging relaxation oscillator of FIG. 4C. Graph 600 includes the voltage 658 at node 355 on capacitor 351 with respect to time. Voltage 658 increases at a first charging rate 601 (e.g., fast positive rate) for a fixed time 659. After the fixed time 659, voltage increases at a second charging rate 602 (e.g., slow positive rate), which is less than the first charging rate 601 until the voltage reaches threshold voltage V_{TH} 660.

In another embodiment, voltage 658 may increase at three charging rates. The first and third charging rates being less than the second charging rate. This may allow some initial setup time for synchronizing signals. The second charging rate allows the sensor element to be pre-charged for a fixed amount of time. After the fixed amount of time, the third charging rate may allow for a slower charging rate, as the voltage reaches the voltage threshold. Alternatively, other combinations of two or more charging rates may be used to charge the sensor element.

FIG. 6B illustrates a graph for comparison of one embodiment of detecting a presence of a finger using the dual-slope charging relaxation oscillator of FIG. 4C with the conventional relaxation oscillator. Graph 650 shows an example for detecting finger presence (increased capacitance) with the traditional single slope relaxation oscillator method 651 and the dual-slope charging relaxation oscillator method 652.

The traditional single slope relaxation oscillator method 651 includes the voltages on the sensor element when detecting a finger and when not detecting a finger, represented as voltages 158b and 158a, respectively. In the traditional method 651 both voltages increase using a single charging rate, and a single discharging rate. It should be noted in this example when the sensor element is discharged it is a step function, resulting in an infinite rate of discharge (e.g., infinite discharge). In reality, however, the discharge may not be infinite because it may take a short time to discharge the capacitance, for example, the discharge may be done through a field-effect transistor (FET) with resistive properties. Accordingly, during the short discharge with a FET with resistive properties, the voltage may actually follow an exponential curve, instead of a constant linear curve or infinite discharge. The term “single discharge rate” is used herein merely to distinguish the embodiments described herein that include multiple discharge rates. Both voltages 158a and 158b on the sensor element increase at the single charging rate until the voltage threshold V_{TH} 660 is reached. After the threshold voltage V_{TH} 660 is reached, the sensor element is discharged at a single discharge rate (e.g., infinite rate). This process repeats for either a certain configurable number of cycles (period measurement method) or a fixed time (frequency measurement method).

The dual-slope relaxation oscillator method 652 includes the voltages on the sensor element when detecting a finger and when not detecting a finger, represented as voltages 658b and 658a, respectively. In the dual-slope method 652 both voltages increase using two charging rates. The first charging rate is for a fixed amount of time, and the second charging rate is until the threshold voltage V_{TH} 660 is reached. After the threshold voltage V_{TH} 660 is reached, the sensor element is discharged at a single discharge rate. This process repeats for either a certain configurable number of cycles (period measurement method) or a fixed time (frequency measurement method). Accordingly, the total time is much smaller when using dual-slope (bottom) for a certain number of cycles than the traditional method (top), while the signal magnitudes (measured difference) remain the same

In the dual-slope example 652, a charging current of five times the nominal charging current is used for a short fixed period (t₀) of time in the beginning of each charge cycle. As can be seen, the dual-slope method is significantly faster and achieves the same result in detecting the presence of the finger. The result is the measured difference between a finger being present and not, indicated by the two arrows in the graph (603).

FIG. 7A illustrates a graph of one embodiment of detecting a presence of a finger using the dual-slope charging relaxation oscillator using two charging rates and two discharging rates. Graph 700 includes the voltage 757 at node 355 on capacitor 351 with respect to time as the capacitor is charged to the threshold voltage V_{TH1} 660 using the dual-slope charging relaxation oscillator described herein. Voltage 757 increases at a first charging rate 701 (e.g., fast positive rate) for a fixed time 758. After the fixed time 758, voltage increases at a second charging rate 702 (e.g., slow positive rate), which is less than the first charging rate 701 until the voltage reaches threshold voltage V_{TH1} 660. After the voltage threshold V_{TH1} 660 is reached, the capacitor is discharged at a first discharging rate 703 (e.g., fast negative rate) for a fixed time 759. After the fixed time 759, voltage decreases (i.e., capacitance discharges) at a second discharging rate 704 (e.g., slow negative rate), which is less than the first discharging rate 703 until the voltage reaches threshold voltage V_{TH2} 760, which is less than the threshold voltage V_{TH1} 660.

FIG. 7B illustrates a graph of one embodiment of detecting a presence of a finger using the dual-slope charging relaxation oscillator using three charging rates and three discharging rates. Graph 750 includes the voltage 761 at node 355 on capacitor 351 with respect to time as the capacitor is charged to the threshold voltage V_{TH1} 660 using the dual-slope charging relaxation oscillator described herein. Voltage 761 increases at a first charging rate 705 (e.g., slow positive rate) for a fixed time 761. After the fixed time 761, voltage 761 increases at a second charging rate 706 (e.g., fast positive rate), which is greater than the first charging rate 705, for a fixed time 762. After the fixed time 762, voltage increases at a third charging rate 707 (e.g., slow positive rate), which is less than the first charging rate 701 until the voltage reaches threshold voltage V_{TH1} 660. After the voltage threshold V_{TH1} 660 is reached, the capacitor is discharged at a first discharging rate 708 (e.g., slow negative rate) for a fixed time 763. After the fixed time 763, voltage decreases (i.e., capacitance discharges) at a second discharging rate 709 (e.g., fast negative rate), which is greater than the first discharging rate 708 for a fixed time 764. After the fixed time 764, voltage decreases (i.e., capacitance discharges) at a third discharging rate 710 (e.g., slow negative rate), which is less than the second discharging rate 709 until the voltage reaches threshold voltage V_{TH2} 760, which is less than the threshold voltage V_{TH1} 660.

In one embodiment, having a slower positive or negative slope (e.g., first charging rate 705 or first discharging rate 708) before a faster positive or negative slope (e.g., second charging rate 706 or second discharging rate 709) may allow time for the device to synchronize clocks. This may allow the device to cleanly identify the direction change before starting the time interval for the faster slope (e.g., charging rate 706 or discharging rate 709). In one embodiment, the oscillator formed by the capacitance is normally asynchronous to the clock that is used to measure the time of the fast-slope interval (e.g., first charging rate 706 to reach the threshold voltage V_{TH1} 660).

Embodiments of the present invention, described herein, include various operations. These operations may be performed by hardware components, software, firmware, or a combination thereof. As used herein, the term “coupled to” may mean coupled directly or indirectly through one or more intervening components. Any of the signals provided over various buses described herein may be time multiplexed with other signals and provided over one or more common buses. Additionally, the interconnection between circuit components or blocks may be shown as buses or as single signal lines. Each of the buses may alternatively be one or more single signal lines and each of the single signal lines may alternatively be buses.

Certain embodiments may be implemented as a computer program product that may include instructions stored on a machine-readable medium. These instructions may be used to program a general-purpose or special-purpose processor to perform the described operations. A machine-readable medium includes any mechanism for storing or transmitting information in a form (e.g., software, processing application) readable by a machine (e.g., a computer). The machine-readable medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory; electrical, optical, acoustical, or other form of propagated signal (e.g., carrier waves, infrared signals, digital signals, etc.); or another type of medium suitable for storing electronic instructions.

Additionally, some embodiments may be practiced in distributed computing environments where the machine-readable medium is stored on and/or executed by more than one computer system. In addition, the information transferred between computer systems may either be pulled or pushed across the communication medium connecting the computer systems.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. A method, comprising:
providing a sensor element; and
measuring a capacitance on the sensor element using two charge rates.

2. The method of claim 1, wherein the two charge rates comprise a first charging rate and a second charging rate, and wherein measuring the capacitance comprises:
charging a sensor element of a sensing device for a fixed time at the first charging rate; and
charging the sensor element at the second charging rate to reach a threshold voltage after charging the sensor element for the fixed time.

3. The method of claim 2, further comprising discharging the measured capacitance using two discharging rates.

4. The method of claim 3, wherein the two discharging rates comprise a first discharging rate and a second discharging rate, and wherein discharging the measured capacitance comprises:
discharging the sensor element for a fixed time at the first discharging rate; and
discharging the sensor element at the second discharging rate to reach a threshold voltage after discharging the sensor element for the fixed time.

5. The method of claim 1, wherein the two charge rates comprise a first discharging rate and a second discharging rate, and wherein measuring the capacitance comprises:
discharging the sensor element for a fixed time at the first discharging rate; and
discharging the sensor element at the second discharging rate to reach a threshold voltage after discharging the sensor element for the fixed time.

6. The method of claim 1, wherein the fixed time is programmable.

7. The method of claim 1, wherein the threshold voltage is programmable.

8. The method of claim 1, wherein the two charge rates comprise a first charging rate and a second charging rate, and wherein the first and second charging rates are linear.

9. The method of claim 1, wherein the two charge rates comprise a first charging rate and a second charging rate, and wherein the first charging rate is exponential.

10. An apparatus, comprising:
a sensor element; and
a capacitance sensor coupled to the sensor element, wherein the capacitance sensor is operable to measure a capacitance on the sensor element using two charge rates.

11. The apparatus of claim 10, wherein the two charge rates comprise a first charging rate and a second charging rate, and wherein the capacitance sensor is operable to charge the sensor element for a fixed time at the first charging rate and to charge the sensor element at the second charging rate to reach a threshold voltage to measure the capacitance on the sensor element.

12. The apparatus of claim 10, wherein the two charge rates comprise a first discharging rate and a second discharging rate, and wherein the capacitance sensor is operable to discharge the sensor element for a fixed time at the first discharging rate and to discharge the sensor element at the second discharging rate to reach a threshold voltage to measure the capacitance on the sensor element.

13. The apparatus of claim 10, wherein the capacitance sensor comprises:
a controller circuit; and
a relaxation oscillator coupled to the controller circuit and the sensor element.

14. The apparatus of claim 13, wherein the controller circuit comprises:
a programmable timer coupled to the relaxation oscillator; and
a logic circuit coupled to the programmable timer and the relaxation oscillator.

15. The apparatus of claim 13, wherein the relaxation oscillator comprises:
a current source to provide a charging current to the sensor element;
a comparator coupled to the current source and the sensor element, wherein the comparator is operable to compare a voltage on the selected sensor element and the threshold voltage; and
a reset switch coupled to the comparator and current source, wherein the reset switch is operable to reset the charging current on the selected sensor element.

16. The apparatus of claim 15, wherein the capacitance sensor comprises a digital counter coupled to the relaxation oscillator, and wherein the digital counter is operable to count at least one of a frequency or a period of a relaxation oscillator output received from the relaxation oscillator.

17. The apparatus of claim 13, wherein the capacitance sensor resides in a processing device, wherein the sensor element and processing device are operable to detect a presence of a conductive object, and wherein the conductive object is at least one of a finger or a stylus.

18. An apparatus, comprising:
a sensor element; and
means for measuring a capacitance of the sensor element using two charge rates.

19. The apparatus of claim 18, wherein the two charge rates comprise a first charging rate and a second charging rate, and further comprising means for charging the sensor element at the first charging rate and at the second charging rate, wherein the first charging rate is different than the second charging rate.

20. The apparatus of claim 18, wherein the two charge rates comprise a first discharging rate and a second discharging rate, and further comprising means for discharging the sensor element at the first discharging rate and at the second discharging rate, wherein the first discharging rate is different than the second discharging rate.
